(19) United States
(12) Patent Application Publication
(10) Pub. No.: US 2024/0128420 A1
(43) Pub. Date: Apr. 18, 2024

(54) DISPLAY PANEL

(71) Applicant: AUO Corporation, Hsinchu (TW)

(72) Inventors: Chia-Hui Pai, Hsinchu (TW); Tai-Tso Lin, Hsinchu (TW); Wen-Hsien Tseng, Hsinchu (TW); Wei-Chieh Chen, Hsinchu (TW); Kuan-Yi Lee, Hsinchu (TW); Chih-Chun Yang, Hsinchu (TW)

(73) Assignee: AUO Corporation, Hsinchu (TW)

(21) Appl. No.: 18/075,417

(22) Filed: Dec. 6, 2022

(30) Foreign Application Priority Data
Oct. 12, 2022 (TW) 111138549

(51) Int. Cl. H01L 33/62; H01L 25/075; H01L 33/22; H01L 33/38

(52) U.S. Cl. CPC H01L 33/62; H01L 25/0753; H01L 33/22; H01L 33/382

(57) ABSTRACT

A display panel including a circuit board, a plurality of bonding pads, a plurality of light emitting devices, and a plurality of solder patterns is provided. The bonding pads are disposed on the circuit board, and each includes a first metal layer and a second metal layer. The second metal layer is located between the first metal layer and the circuit board. The first metal layer includes an opening overlapping the second metal layer. A material of the first metal layer is different from a material of the second metal layer. The light emitting devices are electrically bonded to the bonding pads. Each of the solder patterns electrically connects one of the light emitting devices and one of the bonding pads. The solder patterns each contact the second metal layer through the opening of the first metal layer of one of the bonding pads to form a eutectic bonding.

### CROSS-REFERENCE TO RELATED APPLICATION

This application claims the priority benefit of Taiwan application serial no. 111138549, filed on Oct. 12, 2022. The entirety of the above-mentioned patent application is hereby incorporated by reference herein and made a part of this specification.

### BACKGROUND

### Technical Field

The disclosure relates to a display, and more particularly, to a display panel.

### Description of Related Art

In recent years, micro LED display has gradually attracted investment attention of various technology manufacturers. In addition to the advantages of low power consumption and long material life, micro LED displays also have excellent optical performance, such as high color saturation, fast response velocity, and high contrast. In order to achieve lower production cost and larger product design margin, the manufacturing technique of micro LED display adopts die transfer method. For example: the die manufacturer needs to first make (or place) the micro LED die required by the client on a temporary storage substrate, and then the micro LED die stored on the temporary storage substrate is transferred by the client to the circuit boards of drivers of different products according to different application requirements.

Generally speaking, in the bonding process of the micro LED and the circuit board, a solderless layer is needed to stabilize the bonding between the micro LED and the bonding pads on the circuit board. However, if the material of the solderless layer and the bonding pads are not well matched, it is easy to cause overflow or poor bonding of the solderless layer. Therefore, the flexibility of selection of bonding pads material and solderless is limited. How to increase the flexibility of the selection of bonding materials and avoid the problems of solderless overflow and poor bonding at the same time is an urgent problem to be solved.

### SUMMARY

The disclosure provides a display panel with better bonding yield of light emitting devices.

The display panel of the disclosure includes a circuit board, multiple bonding pads, multiple light emitting devices, and multiple solder patterns. The bonding pads are disposed on the circuit board, and each includes a first metal layer and a second metal layer. The second metal layer is located between the first metal layer and the circuit board. The first metal layer includes an opening overlapping the second metal layer. A material of the first metal layer is different from a material of the second metal layer. The light emitting devices are electrically bonded to the bonding pads. Each of the solder patterns electrically connects one of the light emitting devices and one of the bonding pads. The solder patterns each contact the second metal layer through the opening of the first metal layer of the one of the bonding pads, thereby forming a eutectic bonding.

Based on the above, in the display panel of an embodiment of the disclosure, the bonding pads used to bond the light emitting device include a lamination structure of the first metal layer and the second metal layer, and the materials of the two metal layers are different. The first metal layer closer to the light emitting device is provided with an opening exposing a portion of the second metal layer. The solder pattern contacts the second metal layer through the opening of the first metal layer and forms a eutectic bonding. Through the above-mentioned lamination and opening design of the bonding pads, in addition to reducing the overflow of the solder pattern during the bonding process and the loss between the light emitting device and the bonding pads, the eutectic bonding between the solder pattern and the bonding pads is also stabilized.

### BRIEF DESCRIPTION OF THE DRAWINGS

FIG. 1 is a cross-sectional view illustrating a display panel according to a first embodiment of the disclosure.

FIG. 2 is a top schematic view of the display panel of FIG. 1.

FIG. 3 is a cross-sectional schematic view of a display panel according to a second embodiment of the disclosure.

FIG. 4 is a cross-sectional schematic view of a display panel according to a third embodiment of the disclosure.

FIG. 5 is a top schematic view of the display panel of FIG. 4.

### DESCRIPTION OF THE EMBODIMENTS

The usages of “approximately”, “similar to”, “essentially” or “substantially” indicated throughout the specification include the indicated value and an average value having an acceptable deviation range, which is a certain value confirmed by people skilled in the art, and is a certain amount considered the discussed measurement and measurement-related deviation (that is, the limitation of measurement system). For example, “approximately” may indicate to be within one or more standard deviations of the indicated value, such as being within ±30%, ±20%, ±15%, ±10%, or ±5%. Furthermore, the usages of “approximately”, “similar to”, “essentially” or “substantially” indicated throughout the specification may refer to a more acceptable deviation scope or standard deviation depending on measurement properties, cutting properties, or other properties, and all properties may not be applied with one standard deviation.

In the drawings, for clarity, the thickness of layers, films, plates, areas, and the like are magnified. It should be understood that when an element such as a layer, a film, an area, or a substrate is indicated to be “on” another element or “connected to” another element, it may be directly on another element or connected to another element, or an element in the middle may exist. In contrast, when an element is indicated to be “directly on another element” or “directly connected to” another element, an element in the middle does not exist. As used herein, “to connect” may indicate to physically and/or electrically connect. Furthermore, “to electrically connect” may also be used when other elements exist between two elements.

Moreover, relative terms such as “below” or “bottom” and “above” or “top” may serve to describe the relation between one element and another element in the text according to the illustration of the drawings. It should also be understood that the relative terms are intended to include different orientations of a device in addition to the orientation shown in the drawings. For example, if a device in the accompanying drawings is flipped, an element described as being on the “lower” side of other elements shall be re-orientated to be on the “upper” side of other elements. Thus, the exemplary term “lower” may cover the orientations of “upper” and “lower”, depending on the specific orientations of the accompanying drawings. Similarly, if a device in the accompanying drawings is flipped, an element described as being “below” other elements shall be re-orientated to be “above” other elements. Thus, the exemplary term “above” or “below” may cover the orientations of above and below.

Exemplary embodiments are described with cross-sectional views of schematic illustrations of ideal embodiments. Thus, shape alterations as a result of, for example, manufacturing techniques and/or tolerances can be expected, and the illustrated regions of the embodiments described herein should not be construed to particular shapes but include shape deviations due to, for example, manufacturing. For example, regions shown or described as being flat may generally have rough and/or non-linear features. Furthermore, the acute angles shown may be round. Therefore, the regions illustrated in the drawings are only schematic representations and are not intended to illustrate the exact shapes of the regions or to limit the scope of the claims.

References of the exemplary embodiments of the disclosure are to be made in detail. Examples of the exemplary embodiments are illustrated in the drawings. If applicable, the same reference numerals in the drawings and the descriptions indicate the same or similar parts.

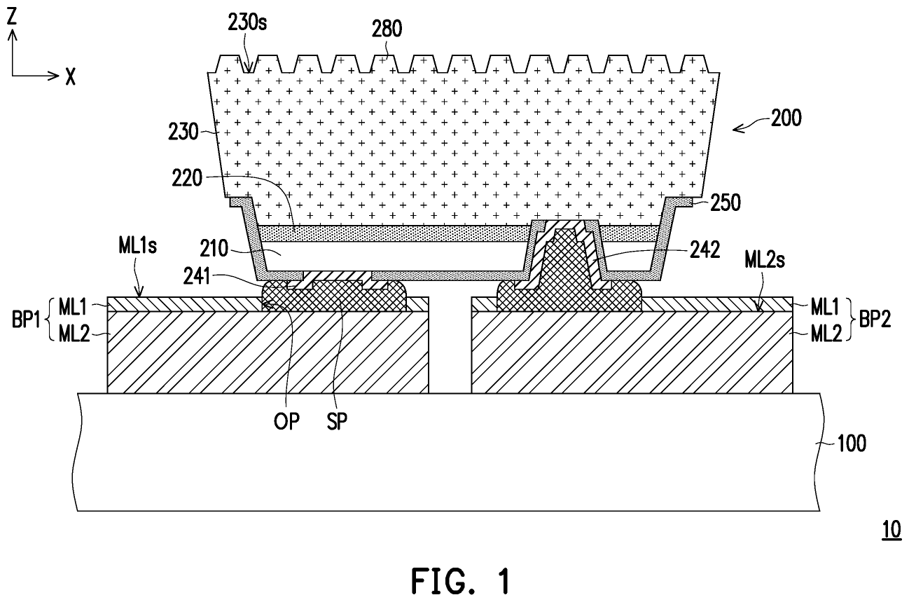

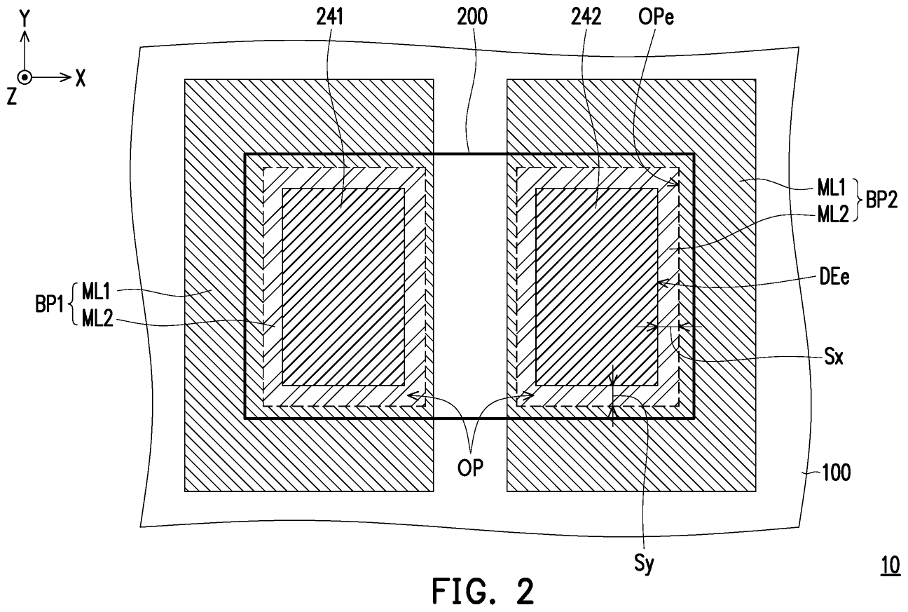

FIG. 1 is a cross-sectional view illustrating a display panel according to a first embodiment of the disclosure. FIG. 2 is a top schematic view of the display panel of FIG. 1. For clarity, FIG. 2 omits the illustration of the solder pattern SP of FIG. 1. Referring to FIG. 1 and FIG. 2, a display panel 10 includes a circuit board 100, multiple bonding pads BP1, multiple bonding pads BP2, multiple light emitting devices 200, and multiple solder patterns SP. The bonding pads BP1 and the bonding pads BP2 are disposed on the circuit board 100 and are electrically connected to the circuit board 100. The light emitting devices 200 are electrically bonded to the bonding pads.

In this embodiment, the light emitting device 200 is, for example, a flip-chip type light emitting diode (LED). A bonding pad BP1 and a bonding pad BP2 adjacently arranged along a direction (e.g., direction X) are adapted for bonding a light emitting device 200. However, the disclosure is not limited thereto. In other embodiment, the light emitting device may also be a vertical type LED, and the number of the bonding pads for bonding the vertical type LED may be one.

In order to electrically conduct the light emitting device 200 and the bonding pads (e.g., the bonding pad BP1 and the bonding pad BP2), a solder pattern SP is provided between the light emitting device 200 and the bonding pads. In addition to providing the electrical connection between the light emitting device 200 and the bonding pads, the solder pattern SP may also stably fix the light emitting device 200 on the circuit board 100.

Furthermore, the bonding pads BP1 and the bonding pads BP2 each include a first metal layer ML1 and a second metal layer ML2 with materials that are different from each other. The second metal layer ML2 is located between the first metal layer ML1 and the circuit board 100. It should be noted that an angle of contact of the first metal layer ML1 to a material of the solder patterns SP is greater than an angle of contact of the second metal layer ML2 to a material of the solder patterns SP. Preferably, the angle of contact between the first metal layer ML1 and the material of the solder patterns SP is greater than 90 degrees, and the angle of contact of the second metal layer ML2 and the material of the solder patterns SP is less than 90 degrees. That is, the solder pattern SP is easier to achieve wetting on the second metal layer ML2, while it is easier to achieve de-wetting on the first metal layer ML1 and is difficult to be extended.

From another viewpoint, a solderability of the first metal layer ML1 to the solder patterns SP is less than a solderability of the second metal layer ML2 to the solder patterns SP. Preferably, the solderability of the first metal layer ML1 to the solder patterns SP is less than 50%, and the solderability of the second metal layer ML2 to the solder patterns SP is more than 95%. For example, the material of the first metal layer ML1 may include tungsten nickel (WNi), the material of the second metal layer ML2 may include copper (Cu), nickel gold (NiAu), or a combination thereof, and the material of the solder patterns SP may include tin (Sn), but not limited thereto.

In particular, the first metal layer ML1 includes an opening OP. The opening OP overlaps the second metal layer ML2 along a laminating direction (e.g., direction Z) of the two metal layers, and exposes a portion of a surface ML2s of the second metal layer ML2. The solder pattern SP may contact the second metal layer ML2 through the opening OP of the first metal layer ML1 and form a eutectic bonding. Due to the high stability of the eutectic bonding between the solder pattern SP and the second metal layer ML2, the bonding between the light emitting device 200 and the bonding pads is stabilized.

On the other hand, since the solderability of the first metal layer ML1 to the solder pattern SP is low, in the bonding process of the light emitting device 200 and the bonding pads, the solder pattern SP is less likely to be extended on the first metal layer ML1. Therefore, in the bonding process, the solder pattern SP may be roughly limited within the opening OP of the first metal layer ML1. In other words, it is possible to prevent the solder pattern SP from overflowing during the bonding process, which results in the formation of a cavity between the light emitting device 200 and the bonding pads, thereby ensuring electrical continuity between the light emitting device 200 and the bonding pads.

For example, in this embodiment, after the bonding process of the light emitting device 200 and the bonding pads is completed, the solder patterns SP are only distributed in the opening OP of the first metal layer ML1, and does not overlap a surface ML1s of the first metal layer ML1 away from the second metal layer ML2, but not limited thereto.

In this embodiment, the light emitting device 200 includes a type 1 semiconductor layer 210, a light emitting layer 220, a type 2 semiconductor layer 230, an element electrode 241, an element electrode 242, and an insulating layer 250. The light emitting layer 220 is sandwiched between the type 1 semiconductor layer 210 and the type 2 semiconductor layer 230. The type 1 semiconductor layer 210 is, for example, a P-type semiconductor layer, the type 2 semiconductor layer 230 is, for example, an N-type semiconductor layer, and the light emitting layer 220 is, for example, a multiple quantum well (MQW) layer. It should be noted that the respective materials and structures of the type 1 semiconductor layer 210, the light emitting layer 220, and the type 2 semiconductor layer 230 may be obtained from any semiconductor layer and any light emitting layer known to those skilled in the art for forming a light emitting device, and the disclosure is not limited by the contents disclosed in the drawings.

Furthermore, the insulating layer 250 overlaps the type 1 semiconductor layer 210, the light emitting layer 220, and the type 2 semiconductor layer 230. The element electrode 241 and the element electrode 242 penetrate through the overlapping insulating layer 250 to electrically connect the type 1 semiconductor layer 210 and the type 2 semiconductor layer 230 respectively. The element electrode 241 and the element electrode 242 overlap the two opening OPs of the bonding pads BP1 and the bonding pads BP2 along the direction Z, respectively. The solder pattern SP is connected between the element electrode of the light emitting device 200 and the bonding pads.

It should be noted that in this embodiment, an orthographic projection area of the opening OP of each of the first metal layer ML1 of the bonding pads BP1 and the bonding pads BP2 on the circuit board 100 may be greater than an orthographic projection area of each of the element electrode 241 and the element electrode 242 on the circuit board 100, but not limited thereto. In another not shown embodiment, the orthographic projection area of the opening of the first metal layer of the bonding pads on the circuit board 100 may also be approximately equal to the orthographic projection area of the element electrode of the light emitting device on the circuit board 100.

In this embodiment, the first metal layer ML1 further includes an opening edge OPe defining the opening OP. The element electrode 241 and the element electrode 242 each have an electrode edge DEe. Two orthographic projections of the opening edge OPe of the first metal layer ML1 and the electrode edge DEe of the element electrode on the circuit board 100 are provided with a shortest pitch along at least one direction, and the shortest pitch may be no less than 5 micrometers and no more than 13 micrometers, and the shortest pitch may be no less than 5 micrometers and no more than 13 micrometers.

For example, in this embodiment, an orthographic projection profile of the opening OP of the first metal layer ML1 and the element electrode of the light emitting device 200 on the circuit board 100 may be a rectangle. The two orthographic projections of the opening edge OPe of the first metal layer ML1 and the electrode edge DEe of the element electrode on the circuit board 100 is provided with a shortest pitch Sx along the direction X and a shortest pitch Sy along the direction Y. The shortest pitch Sx and the shortest pitch Sy may be the same or different.

However, the disclosure is not limited thereto. According to other embodiment, orthographic projection profiles of the opening of the first metal layer and the element electrode of the light emitting device on the circuit board may be different from each other, and are circular, square, or other suitable shapes, respectively.

On the other hand, in order to meet the requirements of different light emitting types, the light emitting device 200 may optionally be provided with multiple optical microstructures 280 on a surface 230s of the type 2 semiconductor layer 230 away from the circuit board 100, but not limited thereto.

Other embodiments are described below to explain the disclosure in detail, and the same components will be denoted by the same reference numerals, and the description of the same technical content will be omitted. For the description of the omitted part, reference may be made to the above embodiment, and details are not described in the following embodiments.

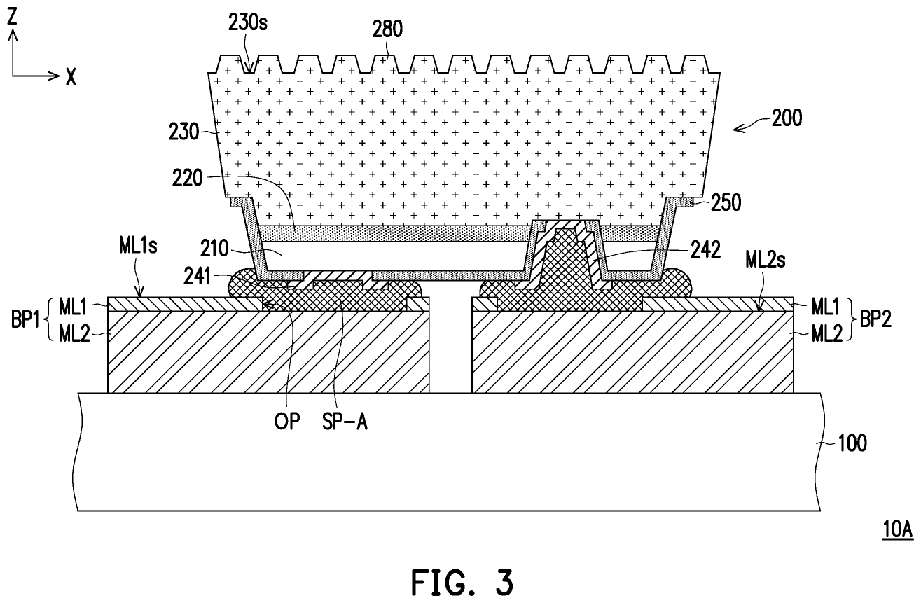

FIG. 3 is a cross-sectional schematic view of a display panel according to a second embodiment of the disclosure. Referring to FIG. 3, the difference between the display panel 10A of this embodiment and the display panel 10 of FIG. 1 is that the solder pattern has a different extension state on the bonding pads. Specifically, unlike the solder pattern SP shown in FIG. 1, the solder pattern SP-A of the embodiment may be further extended to the outside of the opening OP and contact the surface ML1s of the first metal layer ML1. In particular, an increase in contact area between the solder pattern SP-A of this embodiment and the first metal layer ML1 helps to form the eutectic bonding between the solder pattern SP-A and the first metal layer ML1. In other words, in addition to the eutectic bonding between the second metal layer ML2 and the solder pattern SP-A, the bonding between the light emitting device 200 and the bonding pads may be further stabilized through the eutectic bonding between the first metal layer ML1 and the solder pattern SP-A.

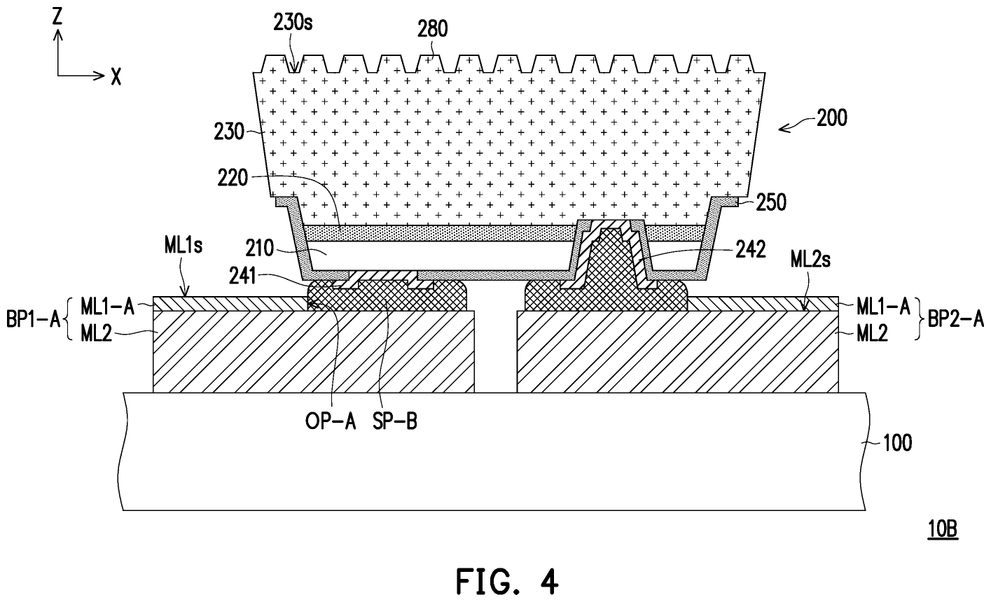

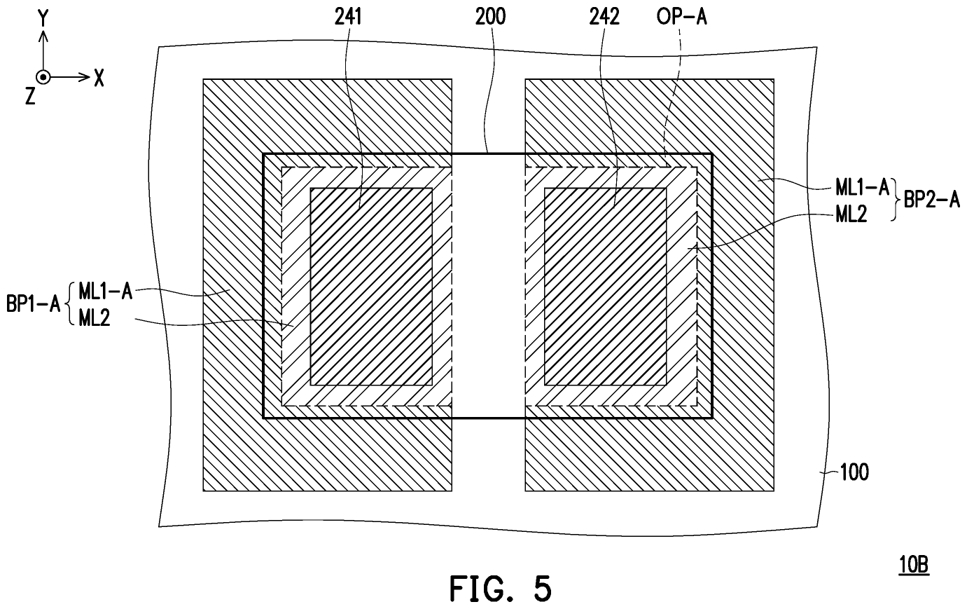

FIG. 4 is a cross-sectional schematic view of a display panel according to a third embodiment of the disclosure. FIG. 5 is a top schematic view of the display panel of FIG. 4. Referring to FIG. 4 and FIG. 5, the difference between the display panel 10B of this embodiment and the display panel 10 of FIG. 1 is that the configuration of the opening of the first metal layer is different. For example, in this embodiment, an opening OP-A of the first metal layers ML1-A of the bonding pads BP1-A and the bonding pads BP2-A is a non-enclosed opening. That is, the opening edge of the first metal layer ML1-A defines that the opening OP-A is not disposed around the element electrode of the light emitting device 200.

From another viewpoint, each of the first metal layers ML1-A of the bonding pads BP1-A and the bonding pads BP2-A do not have any portion extending between the element electrode 241 and the element electrode 242. Thus, the solder pattern SP-B of this embodiment may be further extended to a gap between the bonding pads BP1-A and bonding pads BP2-A, and the contact area of the solder pattern SP-B and the second metal layer ML2 may be increased, so that the bonding between the solder patterns SP-B and the bonding pads may be more stable. Specifically, when a pixel resolution of the display panel 10B is higher, the design of the opening OP-A effectively improves the bonding strength between the light emitting device 200 and the bonding pads.

To sum up, in the display panel of an embodiment of the disclosure, the bonding pads used to bond the light emitting device include a lamination structure of the first metal layer and the second metal layer, and the materials of the two metal layers are different. The first metal layer closer to the light emitting device is provided with an opening exposing a portion of the second metal layer. The solder pattern contacts the second metal layer through the opening of the first metal layer and forms a eutectic bonding. Through the above-mentioned lamination and opening design of the bonding pads, in addition to reducing the overflow of the solder pattern during the bonding process and the loss between the light emitting device and the bonding pads, the eutectic bonding between the solder pattern and the bonding pads is also stabilized.

What is claimed is:

1. A display panel, comprising:
a circuit board;
a plurality of bonding pads, disposed on the circuit board, each of the bonding pads comprises a first metal layer and a second metal layer, the second metal layer is located between the first metal layer and the circuit board, the first metal layer comprises an opening overlapping the second metal layer, and a material of the first metal layer is different from a material of the second metal layer;
a plurality of light emitting devices, electrically bonded to the bonding pads; and
a plurality of solder patterns, wherein each electrically connects one of the light emitting devices and one of the bonding pads, the solder patterns each contact the second metal layer through the opening of the first metal layer of the one of the bonding pads, thereby forming a eutectic bonding.

2. The display panel according to claim 1, wherein an angle of contact of the first metal layer to a material of the solder patterns is greater than an angle of contact of the second metal layer to a material of the solder patterns.

3. The display panel according to claim 2, wherein the angle of contact of the first metal layer to the material of the solder patterns is greater than 90 degrees, and the angle of contact of the second metal layer to the material of the solder patterns is less than 90 degrees.

4. The display panel according to claim 1, wherein a solderability of the first metal layer to the solder patterns is less than a solderability of the second metal layer to the solder patterns.

5. The display panel according to claim 4, wherein the solderability of the first metal layer to the solder patterns is less than 50%, and the solderability of the second metal layer to the solder patterns is more than 95%.

6. The display panel according to claim 1, wherein each of the solder patterns further contacts the first metal layer of the one of the bonding pads, thereby forming a eutectic bonding.

7. The display panel according to claim 6, wherein the first metal layer of each of the bonding pads comprises a surface away from the second metal layer, and each of the solder patterns further contacts the surface of the first metal layer of the one of the bonding pads.

8. The display panel according to claim 1, wherein each of the light emitting devices is provided with an element electrode, the element electrode overlaps the opening of the first metal layer of one of the bonding pads, and an orthographic projection area of the opening of the first metal layer on the circuit board is no less than an orthographic projection area of the element electrode on the circuit board.

9. The display panel according to claim 8, wherein the first metal layer further comprises an opening edge defining the opening and the element electrode comprises an electrode edge, two orthographic projections of the opening edge of the first metal layer and the electrode edge of the element electrode on the circuit board are provided with a shortest pitch along at least one direction, and the shortest pitch is no less than 5 micrometers and no more than 13 micrometers.

10. The display panel according to claim 1, wherein the material of the first metal layer comprises tungsten nickel, and the material of the second metal layer comprises copper.
